(19) United States
(12) Patent Application Publication
(10) Pub. No.: US 2024/0043264 A1
(43) Pub. Date: Feb. 8, 2024

(54) MEMS DEVICE MANUFACTURING

(71) Applicant: Obsidian Sensors, Inc., San Diego, CA (US)

(72) Inventors: Tallis CHANG, San Diego, CA (US); Sean ANDREWS, San Diego, CA (US)

(73) Assignee: Obsidian Sensors, Inc., San Diego, CA (US)

(21) Appl. No.: 18/266,514

(22) PCT Filed: Dec. 9, 2021
(86) PCT No.: PCT/US2021/062674

§ 371 Date: Jun. 9, 2023

Related U.S. Application Data
(60) Provisional application No. 63/123,932, filed on Dec. 10, 2020.

(51) Int. Cl. B81B 7/00; B81C 3/00

(52) U.S. Cl. CPC B81B 7/0006; B81C 3/001; B81B 2201/0207; B81B 2207/07; B81C 2203/035

(57) ABSTRACT

Some embodiments include methods of manufacturing a plurality of MEMS devices, each device including a first material and a second material with different CTE. The method includes providing a carrier with substantially equal CTE as the first material, the carrier comprising a plurality of cavities. The method also includes positioning a plurality of components in respective cavities of the carrier, the components comprising the second material. In some embodiments, the method includes positioning a layer of the first material on the second material components. In some embodiments, the method includes bonding the first material layer and the second material components. The method also includes removing the carrier and singulating the first material layer to produce the plurality of MEMS devices.

### CROSS REFERENCE TO RELATED APPLICATIONS

This application claims benefit of U.S. Provisional Application No. 63/123,932, filed Dec. 10, 2020, the entire disclosure of which is herein incorporated by reference for all purposes.

### BACKGROUND

In microelectromechanical system (MEMS) device manufacturing, bonding is frequently a necessary step to join two portions of a device, for example, during a packaging step. Traditional bonding typically includes inserting a bonding material between the two portions of the device and then adhering the two portions with the bonding material. The inventors have discovered that the traditional approaches are deficient and lead to unreliable MEMS devices.

When bonding two materials in MEMS devices (e.g., bonding glass to silicon), a coefficient of thermal expansion (CTE) mismatch can lead to alignment deviations, which can lead to bonding or other manufacturing errors. The deviations can stem from different shrinkage rates (caused by the different CTEs) after the layers are heated for bonding (up to 350 C in some processes) and allowed to cool. These deviations increase as manufacturing scale increases—a panel level manufacturing process with a CTE mismatch will experience more manufacturing errors than the same process at wafer scale.

In another example, the inventors discovered additional deficiencies in bonding two portions of a MEMS device. For example, vacuum packaging (using solder (e.g., solder preforms, deposited solder) as a bonding material, for example) commonly suffers from excess bonding material being squeezed out from between the two bonding interfaces during the bonding process. For example, since solder preforms must be thick enough to survive mechanical handling, they frequently have a minimum thickness and, hence, minimum volume; for this reason, the amount of excess material, when bonding using preforms, is especially problematic when the minimum volume is greater than the volume needed in a manufacturing process. The excess solder volume is squeezed-out from the bonding region and can adversely affect the reliability of a MEMS device if the excess solder is captured within the sealed volume, as the excess solder can damage and/or destroy the devices inside the sealed volume. Excess solder outside the cavity can also be detrimental. For example, squeezed out solder can remain between a die, which can damage wafer dicing blades, leading to lower manufacturing yield.

### SUMMARY

Some embodiments include methods of manufacturing a plurality of MEMS devices, each device including a first material and a second material with different CTE. The method includes providing a carrier with substantially equal CTE as the first material, the carrier comprising a plurality of cavities. The method also includes positioning a plurality of components in respective cavities of the carrier, the components comprising the second material. In some embodiments, the method includes positioning a layer of the first material on the second material components. In some embodiments, the method includes bonding the first material layer and the second material components. The method also includes removing the carrier and singulating the first material layer to produce the plurality of MEMS devices. In some embodiments, the first and second material are selected from glass and silicon.

Advantageously, methods of manufacturing described herein reduce manufacturing errors caused by layers' CTE mismatch. For example, methods described herein reduce the result of CTE mismatch (e.g., between a glass layer of a MEMS device and a silicon component of the MEMS device) to the width of the MEMS device. This advantageously provides for better aligned and bonded MEMS devices, for better scaling, and also allows for freedom in selecting material combinations (e.g., glass and silicon) for MEMS devices.

Some embodiments include a method of manufacturing a MEMS device, where the method includes a first step of providing a first portion of the device, a second step in which grooves are added to the first portion at a bond region of the device, a third step of aligning a second portion of the device with the first portion, a fourth step in which the first portion and second portion are moved toward each other, and a fifth step wherein the first and second portions are bonded at the bond region. Advantageously, the grooves can provide for a tight bond while reducing potentially harmful spillover from the bonding region to the electromechanical components of the MEMS device. Accordingly, reliability of the MEMS devices is improved. In some embodiments, one or more of the first through fifth steps are performed in a vacuum. In some embodiments, some steps are performed in a vacuum (e.g., the third through fifth steps) and other steps may not be.

Some embodiments include a method of manufacturing a plurality of MEMS devices, where the method includes: a step of providing a plurality of first electromechanical components; a step in which a carrier is provided, the carrier including a plurality of positions, each associated with a respective one of the plurality of first electromechanical components; a step of identifying a defective component in the plurality of first electromechanical components; a step of providing a plurality of second electromechanical components; a step of positioning the plurality of second electromechanical components at respective positions on the carrier but not a position associated with the defective electromechanical component; a step in which respective pairs of first and second electromechanical components are bonded; and (optional) a step of singulating the respective pairs of first and second electromechanical components to produce the plurality of MEMS devices. Advantageously, such methods may reduce wasted components by reducing the number of first components bonded to inoperable second components.

### BRIEF DESCRIPTION OF THE DRAWINGS

FIG. 1 depicts a method of manufacturing a plurality of MEMS devices, in accordance with an embodiment;

FIG. 2A depicts an arrangement in a method of manufacturing a plurality of MEMS devices, in accordance with an embodiment;

FIG. 2B depicts another arrangement in a method of manufacturing a plurality of MEMS devices, in accordance with an embodiment;

FIG. 2C depicts another arrangement in a method of manufacturing a plurality of MEMS devices, in accordance with an embodiment;

FIG. 2D depicts another arrangement in a method of manufacturing a plurality of MEMS devices, in accordance with an embodiment;

FIG. 2E depicts another arrangement in a method of manufacturing a plurality of MEMS devices, in accordance with an embodiment;

FIG. 2F depicts another arrangement in a method of manufacturing a plurality of MEMS devices, in accordance with an embodiment;

FIG. 3A depicts exemplary spacing in a 150 mm wafer in a method of manufacturing a plurality of MEMS devices, in accordance with an embodiment;

FIG. 3B depicts exemplary bonding regions of a component in a method of manufacturing a plurality of MEMS devices, in accordance with an embodiment;

FIG. 3C depicts exemplary spacing in a 156 mm wafer in a method of manufacturing a plurality of MEMS devices, in accordance with an embodiment;

FIG. 3D depicts exemplary spacing in a 156 mm wafer in a method of manufacturing a plurality of MEMS devices, in accordance with an embodiment;

FIG. 4 depicts exemplary spacing in a 200 mm wafer in a method of manufacturing a plurality of MEMS devices, in accordance with an embodiment;

FIG. 5 depicts a method of manufacturing a plurality of MEMS devices, in accordance with an embodiment;

FIG. 6A depicts a MEMS device, in accordance with an embodiment.

FIG. 6B depicts a MEMS device, in accordance with an embodiment;

FIG. 7A depicts a MEMS device, in accordance with an embodiment;

FIG. 7B illustrates an exemplary relationship between solder and groove, in accordance with an embodiment;

FIG. 8 depicts a method of manufacturing a plurality of MEMS devices, in accordance with an embodiment;

FIG. 9 depicts a method of manufacturing a plurality of MEMS devices, in accordance with an embodiment.

FIG. 10 illustrates a method of manufacturing an electromechanical system, according to embodiments of the disclosure.

FIG. 11 illustrates an exemplary sensor, according to embodiments of the disclosure.

### DETAILED DESCRIPTION

In the following description of embodiments, reference is made to the accompanying drawings which form a part hereof, and in which it is shown by way of illustration specific embodiments which can be practiced. It is to be understood that other embodiments can be used and structural changes can be made without departing from the scope of the disclosed embodiments.

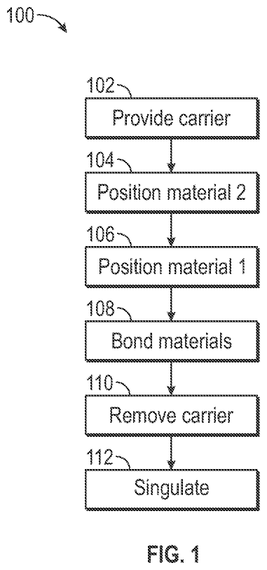

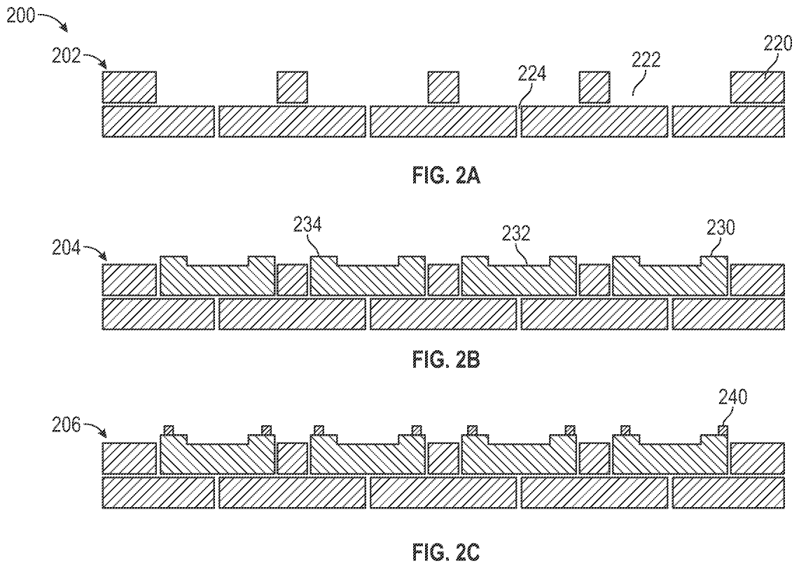

An exemplary method of manufacturing a plurality of MEMS devices will now be described with respect to FIGS. 1 and 2A-2F. Method 100, depicted in FIG. 1, is a method of manufacturing a MEMS devices wherein each device includes a first material and a second material with different CTE. In some embodiments, the first material is glass and provides a substrate for components (thin film transistors, e.g.) in the MEMS devices. In some embodiments, the second material is silicon and provides a cover in the MEMS device. As will be appreciated by those skilled in the art, other embodiments reverse the glass and silicon in the MEMS device, glass and a different material, silicon and a different material, or use different first and second materials.

Method 100 includes step 102, providing a carrier with substantially equal CTE as the first material, the carrier including a plurality of cavities. The method continues with step 104, positioning a plurality of components in respective cavities of the carrier, each component including the second material. Step 106 includes positioning a layer of the first material on the second material components. Method 100 also includes step 108, bonding the first material layer and the second material components, and step 110, removing the carrier. Method 112 continues with singulating the first material layer to produce the plurality of MEMS devices.

Method 100 can be performed at any scale, including panel scale manufacturing, wafer scale manufacturing, etc. In some embodiments, two layers in a manufacturing process can be understood to have “substantially equal CTE” a difference in respective CTEs does not cause the layers to deviate, when heat for bonding is applied/removed, such that bonding and/or alignment of the second material components and first material layer fall outside manufacturing tolerances. Tolerances will depend on the particular application. For example, the tolerance may be 50 micron deviation of a device cover at an 8 inch wafer edge at 300 C bonding temperature. Two materials can be understood to have “different CTE” when they do not have substantially equal CTE.

Advantageously, methods of manufacturing described herein reduce manufacturing errors caused by layers' CTE mismatch. For example, methods described herein reduce the result of CTE mismatch (e.g., between a glass layer of a MEMS device and a silicon component of the MEMS device) to the width of the MEMS device. This advantageously provides for better aligned and bonded MEMS devices, and also allows for freedom in selecting combinations (e.g., glass and silicon) for MEMS devices.

Further, methods described herein may also improve the accuracy of singulating techniques and improve manufacturability by not requiring specialty equipment. For example, embodiments herein do not require infrared camera to remove portions of a second material (e.g., silicon) before singulating the devices. Embodiments herein also advantageously increase yield and reduce manufacturing costs. For example, embodiments here reduce or remove the need to dice through 2 substrates simultaneously (or the need for two partial cuts on either side).

FIG. 2A depicts arrangement 202 in a method of manufacturing a plurality of MEMS devices, in accordance with an embodiment. Arrangement 202 may be associated with a step of providing a carrier, such as step 102 in method 100. In arrangement 202, carrier 220 includes a plurality of cavities 222, each cavity including a vacuum channel 224. In some embodiments, each cavity does not comprise a vacuum channel.

In some embodiments, providing a carrier includes providing a layer of material with substantially equal CTE as the first material. In some embodiments, providing a carrier includes providing a carrier layer of the first material. In some embodiments, the first material is glass, and providing the carrier includes providing a different glass, but one that has substantially equal CTE as a glass used in the MEMS devices. In some embodiments, providing a carrier includes providing a ceramic material (e.g., Al₂O₃) or a metal (e.g., Kovar).

In some embodiments, providing a carrier includes providing a first carrier layer, providing a second carrier layer, bonding the first and second carrier layers, and removing material from one or both of the first and second carrier layers to create the plurality of cavities. In some embodiments, removing material from one or both of the first and second layers includes providing an etch stop layer between the layers and etching one or both of the first and second layers to the etch stop. In other embodiments, material is removed from one or both of the first and second layers before the layers are bonded.

In some embodiments, providing a carrier includes providing cavities of 0.5 mm depth. In some embodiments, the cavity is 24-27 mm wide and 14-16 mm long. For example, a cavity could be 24 mm×16 mm×0.5 mm or another could be 27 mm×14 mm×0.5 mm.

In some embodiments, the carrier is a round wafer or a square wafer. The wafer can be, for example, 4 inches, 6 inches, 8 inches, or 12 inches. In some embodiments, the carrier is panel-sized.

FIG. 2B depicts arrangement 204 in a method of manufacturing a plurality of MEMS devices, in accordance with an embodiment. Arrangement 204 may be associated with a step of positioning a plurality of second material components, such as step 104 in method 100. Arrangement 204 includes a plurality of components 230 positioned in respective cavities of the carrier 220. Each component 230 includes sidewalls 234 defining a cavity 232 in the component.

In some embodiments, the second material is silicon and the first material is glass. In such embodiments, the CTE mismatch may be 0.3-0.8 ppm.

In some embodiments, positioning a plurality of components includes applying a vacuum to the components to secure the components to the carrier. In some embodiments, applying a vacuum includes applying a vacuum to the components through a channel in the carrier, e.g., channel 224. In some embodiments, a vacuum is not applied to the components. In such embodiments, channel 224 may not be added to carrier 220. In some embodiments, a vacuum is applied through channel 224 for the purpose of evacuating a region under the components 230. Such channels may advantageously allow for a vacuum to be applied after the components 230 are positioned on carrier 220, removing air that may get trapped between the components 230 and the carrier 220.

In some embodiments, the components correspond to covers in the plurality of MEMS devices.

In some embodiments, each component includes side walls with a metalized surface. In some embodiments, each component's sidewalls define a cavity in the second material component. In some embodiments, the components are provided to the manufacturing process with the cavity already defined. In other embodiments, the cavity is defined while the components are positioned in the cavities of the carrier. Similarly, the metalized surfaces on the components' sidewalls may be provided before positioning the components in the respective cavities or may be added after the components are positioned in the cavities of the carrier. In some embodiments, bonding the first material layer and the second material components includes depositing bonding components on the metalized surfaces. In such embodiments, the bonding components can include solder preforms. In some embodiments, the bonding components can include deposited solder. In some embodiments, the sidewalls are approximately 1-2 mm wide (in such embodiments, the bonding components (e.g., solder preforms, deposited solder) described herein may be 500 microns wide). In some embodiments, the sidewalls are on the order of a few hundred microns. In some embodiments, the second material components can be approximately 725 microns thick (as measured in a direction orthogonal to a plane of the first material carrier).

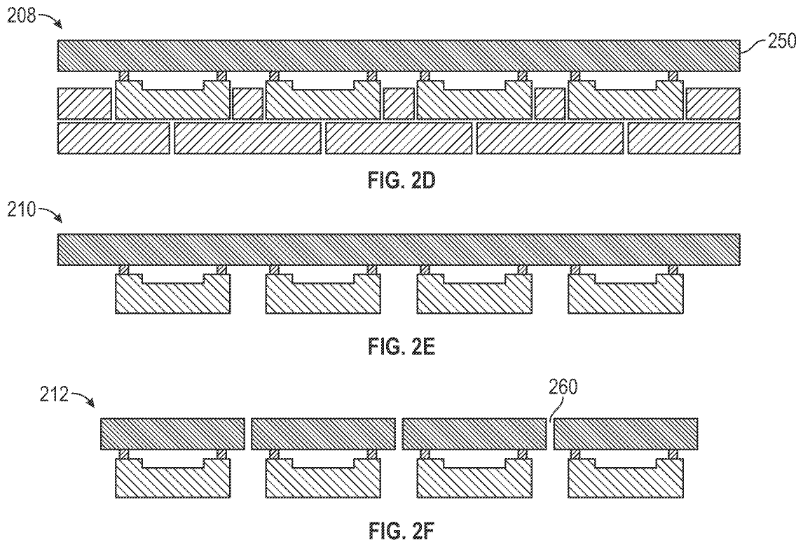

FIG. 2C depicts arrangement 206 in a method of manufacturing a plurality of MEMS devices, in accordance with an embodiment. Arrangement 206 may be associated with a step of bonding a first material layer and second material components, such as step 108 in method 100. In arrangement 206, bonding components 240 are placed on the second material components. After a first material layer is positioned on the second material components (see arrangement 208 in FIG. 2D), the bonding components can be heated to facilitate bonding the first material layer and the second material components. In some embodiments, components are heated before the first material layer is positioned on the second material components. In some embodiments, the bonding components are solder preforms or deposited solder that are placed on components 230 and tacked down in corners of the bonding components (e.g., on the four corner tabs 304 of the preform 302 shown in FIG. 3B). In some further embodiments, the preforms are 25 microns thick (as measured in a direction orthogonal to a plane of the first material carrier).

FIG. 2D depicts arrangement 208 in a method of manufacturing a plurality of MEMS devices, in accordance with an embodiment. Arrangement 208 may be associated with a step of positioning a first material layer on second material components, such as step 106 in method 100. In arrangement 208, first material layer 250 is positioned on the second material components. In some embodiments, first material layer 250 is preprocessed to include components of the MEMS devices. For example, first material 250 is preprocessed with metalized surfaces (e.g., a seal metal ring) that are aligned and bonded with bonding components 240 described above. In some embodiments, first material layer 250 comprises cavities (not shown). Such cavities may be in addition or in replace of cavities 232 in components 230. In some embodiments where first material layer 250 comprises cavities (not shown), the cavities are in addition to or in replace of cavities 222 in layer 220. In some embodiments where layer 220 does not have cavities, vacuum channel 224 is included.

As described below, methods of manufacturing can include, after positioning the first material layer, bonding the first material layer and the second material components. In the example of arrangement 206, bonding components (e.g., solder preforms, deposited solder) were deposited for the bonding. In some embodiments, bonding the first material layer (described below with respect to arrangement 208) and the second material components includes growing bonding components by deposition (e.g., electroplating or vacuum deposition). In some embodiments, bonding the first material layer and the second material components includes increasing the temperature of the arrangement to effectuate bonding. In some embodiments, bonding may be effectuated at about 350 C. In some embodiments, the temperature is increased to approximately 300 C. In such embodiments, the bonding component includes AuSn. In some embodiments, the temperature mismatch may play a greater role, such as in Au—Au thermocompression bonding.

In some embodiments, prior to bonding the first material layer and second material components, a method includes moving the second material components toward the first material layer. This may advantageously allow for efficient bonding of the first and second materials where the height(s) (as measured in a direction orthogonal to a plane of the first material carrier) of the second material components is(are) shorter than the depth (measured in the direction orthogonal to the plane of the first material carrier) of the cavities and/or the second material components have different heights. In such embodiments, a force is applied to move the components toward the material layer. In some embodiments, the force is gravity. In such embodiments, the method includes rotating the first material layer, second material components, and carrier. In other embodiments, the process includes positioning the second material components below (with respect to gravity) the carrier and applying a vacuum (e.g., using the vacuum channels described above with respect to arrangement 202) to hold the components in place until the first material layer is applied (this may be particularly advantageous in packaging environments that are not otherwise in vacuum). When the second material components are then positioned on the first material layer, the vacuum is released, and the second material components move toward the first material by gravity. Then, the first material layer and second material components are bonded. In some embodiments, a different force is used. For example, springs (or similar force) may be applied in the carrier cavities and under the covers, the springs will move the components toward the material layer. Then, the first material layer and second material components are bonded.

FIG. 2E depicts arrangement 210 in a method of manufacturing a plurality of MEMS devices, in accordance with an embodiment. Arrangement 210 may be associated with a step of removing the carrier, such as step 110 in method 100. Comparing arrangement 208 and 210, the carrier 220 has been removed.

FIG. 2F depicts arrangement 212 in a method of manufacturing a plurality of MEMS devices, in accordance with an embodiment. Arrangement 212 may be associated with a step of singulating the first material layer, such as step 112 in method 100. In arrangement 212, the first material layer has been singulated at lines 260. In some embodiments, singulating includes dicing the first material layer using a dicing saw. In some embodiments, singulating includes dicing the first material layer using a scribe and break process.

In some embodiments, method 100 of FIG. 1 and arrangements 202-212 of FIGS. 2A-2F are performed in an environment suitable for the bonding technique employed. Exemplary environments include vacuum, dry nitrogen, inert gas (He, Ar, etc.), dry air, etc. Depending on the device requirements, different gas pressures may be employed.

FIG. 3A depicts exemplary spacing in a 150 mm wafer in a method of manufacturing a plurality of MEMS devices, in accordance with an embodiment. Exemplary spacing between are MEMS devices positions are shown. The MEMS devices are positioned with a border of 5 mm to the edge of the wafer, 5 mm spacing in a first dimension, and 2.05 mm spacing in a second dimension. This arrangement yields 40 components. An outline of a mask is overlayed.

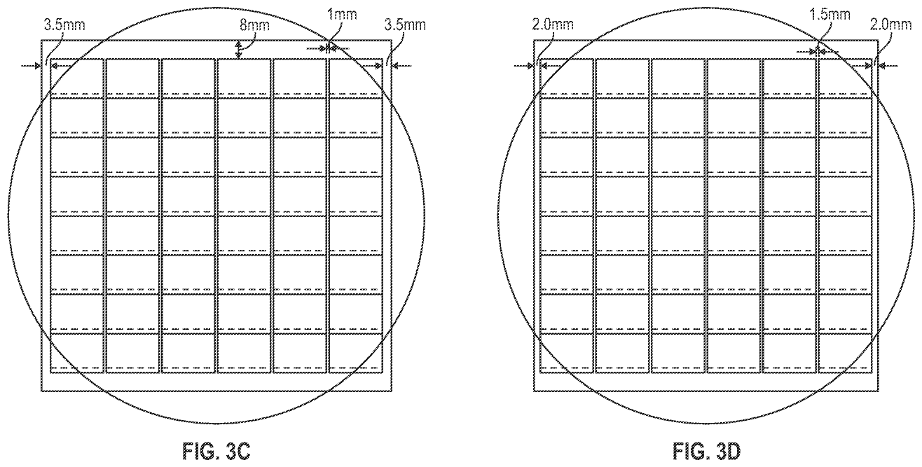

FIG. 3B depicts exemplary bonding regions of a component in a method of manufacturing a plurality of MEMS devices, in accordance with an embodiment. The component in FIG. 3B may correspond to a position of a device in the wafer of FIG. 3A. The bonding region includes four corner tabs 304 of the preform 302. In some embodiments, the bonding region includes four corner tabs 304 of deposited solder 302. Exemplary dimensions are again included for illustrative purposes. The embodiment of FIG. 3B may correspond to the sealing regions discussed herein, for example the bonding components discussed above with respect to FIGS. 1 and 2 and below with respect to FIGS. 5-9.

FIG. 3C depicts exemplary spacing in a 156 mm wafer in a method of manufacturing a plurality of MEMS devices, in accordance with an embodiment. This embodiment is similar to FIG. 3A, but with different spacing on the larger wafer to produce more individual devices (48 in this instance). FIG. 3D depicts exemplary spacing in a 156 mm wafer in a method of manufacturing a plurality of MEMS devices, in accordance with an embodiment. The spacing in FIG. 3D is different than FIG. 3C, but yields the same number of devices.

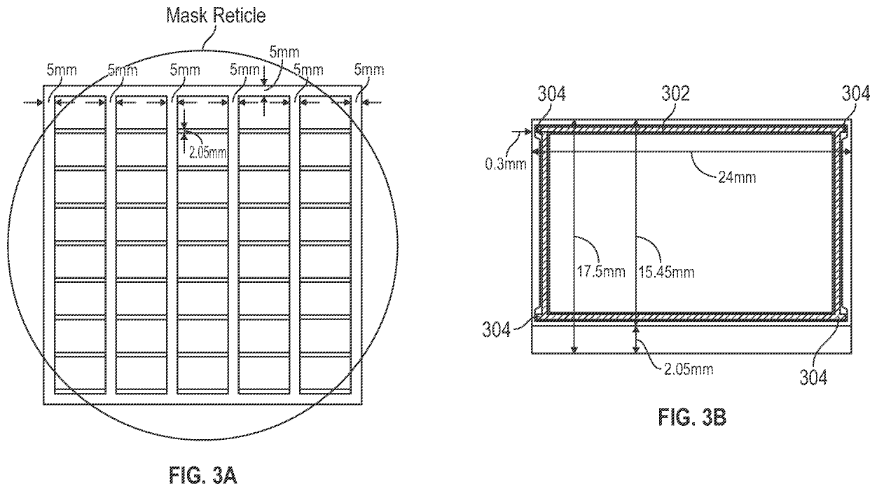

FIG. 4 depicts exemplary spacing in a 200 mm wafer in a method of manufacturing a plurality of MEMS devices, in accordance with an embodiment. This orientation yields 61 devices.

In some embodiments, the first material is glass. In some embodiments, the first material is a borosilicate that contains additional elements to fine tune properties. An example of a borosilicate is by CORNING EAGLE, which produces an alkaline earth boro aluminosilicate (a silicate loaded with boron, aluminum, and various alkaline earth elements). Other variations are available from ASAHI GLASS or SCHOTT.

FIG. 5 depicts a method 500 of manufacturing a MEMS device, in accordance with an embodiment. Method 500 includes a first step 502 of providing a first portion of the device, a second step 504 in which grooves are added to the first portion at a bond region of the device, a third step 506 of aligning a second portion of the device with the first portion, a fourth step 508 in which the first portion and second portion are moved toward each other, and a fifth step 510 wherein the first and second portions are bonded at the bond region. Advantageously, the grooves can provide for a tight bond while reducing and/or controlling the amount of potentially harmful spillover from the bonding region to the electromechanical components of the MEMS device, thereby improving reliability of the MEMS devices. This may be particularly advantageous where a manufacturing process has limited control over the volume of bonding material. For example, solder preform is may need to have a minimum volume to facilitate process handling, but that minimum volume for handling may be more than the maximum volume for bonding; in traditional manufacturing methods, the excess volume may cause spill-over outside the bond regions and harm the reliability and integrity of the MEMS device.

In some embodiments, method 500 includes bonding with solder preform. In some embodiments, method 500 includes bonding with deposited solder. Method 500 can be used in any bonding technique where an excess of bonding material is used. For example, in electroplating typical thickness of the bonding material is on the order of a few microns, while the actual amount at the bonding interface can be much less. Method 500 may be particularly advantageous where the bonding material is in liquid state, at some point during the bonding process. In embodiments where the bonding material is solder preform, method 500 can further include positioning a solder preform over the grooves in the first portion, heating the solder preform, and cooling the solder preform so that the first and second portions bond. In some embodiments, step 510 (the first and second portions are bonded at the bond region) includes heating a material (e.g., solder preform, deposited solder) and allowing it to cool (e.g., passive cooling where heat is allowed to dissipate to the local environment, active cooling where, for example, air is forced over the device, etc.).

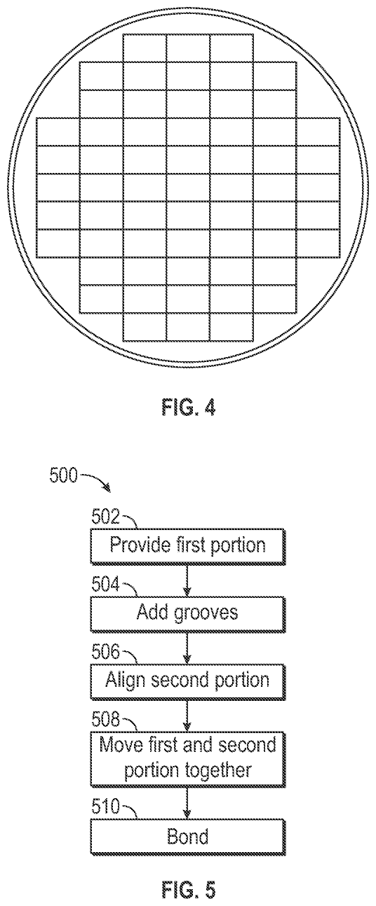

FIG. 6A depicts MEMS device 600 in a cross-sectional view, in accordance with an embodiment. In some embodiments, device 600 is manufactured in accordance with method 500 above. In device 600, substrate 602 is silicon, but other materials could be used. Such materials can include, for example Ge, ZnSe, glass, ceramic, etc. MEMS device 600 includes portion 602 with bond region 604. As used herein, a “bond region” can be understood to mean a region of a device where two portions of a device are adhered. In such devices, both portions of the device have respective “bond regions.” For example, in a MEMS device where a glass portion is bonded to a silicon portion (e.g., a glass portion comprises circuits and/or mechanical components and is bonded to a silicon cover), both the glass portion and silicon portion have respective bond regions where, for example, solder preform or deposited solder is placed to adhere both sides together. A bond region may also be referred to as a “sealing region” in, for example, a manufacturing process with a vacuum encapsulation step.

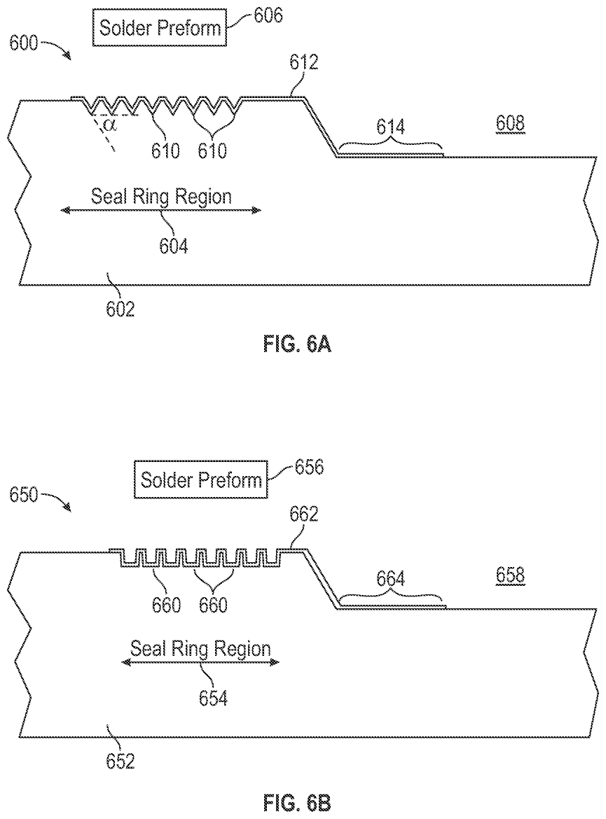

As used herein, a “groove” can be understood to include a topography below a surface in a bond region. For example, in the bond region 604 of device 600, grooves 610 are created below the bond surface of substrate 602. In some embodiments, grooves are created by removing volume from a surface of a substrate (e.g., by etching the substrate, as discussed further herein). In some embodiments, grooves are created by selectively raising the surface (e.g., by a deposition, growth (e.g., with silicide)) of the substrate in the bond region but not raising all the surface in the region. Device 600 depicts eight grooves, but it will be readily appreciated that different numbers of grooves can be used (see, e.g., FIG. 7A). Device 600 illustrates the grooves occupying the entire bond region, but other embodiments may include grooves occupying a portion of the bond region. Further, device 600 illustrates the grooves as contiguous, but the grooves could be spaced (for example, a first groove and a second groove separated by a flat surface). In such embodiments, the spacing of the grooves can be regular or varied. For example, some embodiments include tightly packed grooves toward the edge of the sealing region, but wider groove spacing toward the center of the bond region.

Returning to FIG. 5, the step 504 (adding grooves to the first portion) can include etching the grooves into the first portion. For example, two sidewalls at etched angles to a surface (for example, see angle α, which represents the angle between the surface of substrate 602 and one of the grooves 610 in FIG. 6A) will meet at a point below the surface, providing a natural limit to the depth of the groove. This etching step may advantageously use the crystalline structure of the substrate to control the depth of each groove. More specifically, the etching step may be performed to etch along the crystal planes of the substrate. In some embodiments, the grooves may include side walls angled at about 54 degrees to a surface of the first portion. In some embodiments, at least one side wall is angled at 54.74 degrees to the surface of the first portion.

In some embodiments, the grooves do not form an acute angle with the surface. In FIG. 6B, for example, grooves 660 do not form an acute angle with the surface of substrate 652. FIG. 6B depicts bond region 654 in substrate 652 and solder preform 656 above the grooves 660. An adhesive layer 662 is placed over the grooves 660. In the embodiment of FIG. 6B, the adhesive layer 662 extends to a portion 664 of the cavity 658.

In some embodiments, the depth of the groove is determined by the width of the groove; a desired depth can be achieved by selecting the width of the grooves in combination with a known angle of the sidewalls. For a given depth “D” and angle α, the width “W” of the grooves (and, if the grooves are formed by etch, the width of the etch line) can be determined using the equation: D=(W*tan α)/2. A depth (or width) of the groove may be determined through a desired volume of the groove. For example, consider an embodiment where a bonding component (e.g., solder preform 606 in FIG. 6A, solder preform 656 in FIG. 6B, deposited solder (not shown)) has a first volume (determined by, for example, a volume of the bonding component) and the plurality of grooves define a second volume in the first portion. The amount of solder volume is tuned according to the desired result. If voiding or reduced bond width are acceptable, then the second volume may be desired to be greater than or equal to the first volume to reduce spillover from the bonding region to electromechanical components in the MEMS device (e.g., the spillover enters a cavity of the device that houses electrical and/or mechanical components). On the other hand, if some spillover is acceptable, the second volume may be desired to be less than the first volume to reduce or minimize voiding and/or increase or maximize the bond width. In some embodiments, the groove sizing is a function of area. In these embodiments, a groove depth is constant across applications and only the groove width varies. Some exemplary dimensions include widths of 15-50 microns and depths of 13-45 microns. The length of the groove can depend on the area of the device manufactured; exemplary lengths include, but are not limited to, 50-74 mm. In some embodiments, preform widths are 100-1000 microns with thicknesses of 20-50 microns.

Method 500 can further include a step of adding a cavity to the first portion of the device, wherein the cavity is deeper than the grooves. FIG. 6 depicts exemplary cavity 608 (see also FIGS. 2A-F, 6B, and 7). In some embodiments, a cavity is formed using an etch step. In some embodiments, the cavity and grooves are formed in the same manufacturing step of the device. For example, a same etching step. As described above, the crystalline structure of portion 502 may advantageously provide a limit to the depth of the grooves' etch. Accordingly, a groove can advantageously be formed in a same processing step as a cavity, even though the cavity and groove have different depths, thereby saving manufacturing time and costs (see, e.g., FIG. 6A). In some embodiments, grooves are formed naturally in a separate step from the cavity (see, e.g., FIG. 6B).

In some embodiments, step 506 (aligning a second portion of the device with the first portion 506) includes aligning mutual bond regions of the first and second portions. In some embodiments, aligning includes aligning the grooves of the first portion with a bonding region of the second portion. In embodiments where a second portion includes a metallizing ring on the second portion, aligning the two portions can include aligning the ring with the grooves. In some embodiments, aligning is performed without reference to the bond regions of the first and second portions.

In some embodiments, step 508 (the first portion and second portion are moved toward each other) includes holding one portion stationary while the other is moved so that the first and second portions are moved toward each other. In some embodiments, both portions are moved simultaneously.

FIG. 7A depicts a MEMS devices 700 in a top-down view, in accordance with an embodiment. In some embodiments, device 700 is manufactured using one or more steps of method 500. In some embodiments, device 700 includes aspects of device 600, and vice-versa. Device 700 may correspond to a first portion of a MEMS device, the device also comprising a second portion (not shown) bonded to the first region. Device 700 includes substrate 702 with bond region 704, trenches 706a/706b, cavity 708, and a plurality of sectioned grooves within bond region 704. In some embodiments, a “sectioned groove” has a length shorter than a side of a sealing ring. In some embodiments, the grooves limit the effect of defects. For example, when grooves are parallel to the side of the sealing ring, a defect between the grooves will be confined to the area between the grooves. Other non-parallel groove arrangements can also provide this advantage provided that the topography between grooves is isolated from topography outside the grooves; this arrangement prevents a defect between the grooves from affect areas outside the grooves, thereby reducing the risk of a vacuum break.

In some embodiments where a depth of a groove is self-limited (e.g., using the crystalline structure to limit depth etch, discussed above), the length of a groove is determined by alignment accuracy. In such embodiments, when a groove is perfectly aligned to the crystal orientation, then the length of the groove is unbounded. In embodiments where the groove is misaligned from the crystal orientation, the groove width broadens corresponding to the (length of the groove) multiplied by (tan(theta)), where theta is the angular difference between the groove and the crystal. Some embodiments may limit the length of the groove to satisfy a desired limit on the broadening of the width of the grooves.

In some embodiments, a width of a groove may be dictated by an amount of preform in need of accommodation. For example, the preform is 25 um thick and 500 um wide, with a cross-sectional area of 1.25e4 um². In some embodiments, ˜80% of the preform is accommodated, so the grove widths at 35 um (e.g., after etch formation). In some embodiments, the seal ring width is 750 um, so seventeen 35 um grooves can be fitted. In some embodiments, the lengths of the grooves is dictated by the alignment accuracy of the mask with respect to the crystal of a wafer (e.g., Si wafer). In some embodiments, the length is 1 mm. A higher length may be allowed by improve alignment.

FIG. 7B illustrates an exemplary relationship between preform and groove, in accordance with an embodiment. In some embodiments, the exemplary relationship is associated with a 25 um thick preform. In some embodiments, the preform is rectangular, and its cross-sectional area increases linearly with increasing width for a given thickness (e.g., 25 um). In some embodiments, the groove is triangular with no constraint to its depth, so the area of the groove may become greater than the preform (e.g., around 55 um in width in this example).

Returning to FIG. 7A, the plurality of grooves includes multiple sectioned grooves arranged end-to-end. Grooves 710 and 712 are identified for exemplary purposes. Sectioned groove 710 has first end 710a and second end 710b; sectioned groove 712 has first end 712a and a second end (not shown). The first and second ends may be separated by a bond surface of the substrate. Advantageously, by arranging the sectioned grooves end-to-end, groove formation can be more reliable, e.g., by reducing etching outside of the desired groove areas, thereby limiting unintentional merging between adjacent grooves.

The plurality of grooves may be of different lengths. In device 700, for example, groove 712 is longer than groove 710. In some embodiments, the plurality of grooves have equal length. Further, the sectioned grooves in FIG. 7A are depicted as the same width, but some embodiments may provide grooves of different widths. Similarly, trenches 706a and 706b could the same or different lengths, depths, or widths.

In some embodiments, as illustrated in FIG. 7A, the sectioned grooves may be staggered. In this way, leakage from one sectioned groove to another can be controlled. In some embodiments, again illustrated in FIG. 7A, a sealing ring may not be perfectly rectangular. To advantageously improve bonding in those areas, additional grooves may be added to correspond to the “rounded corners” of the sealing ring; such grooves may not extend the full length of the sealing ring.

Returning to FIG. 5, method 500 can further include a step of adding a metalizing ring to the second portion of the device. For example, in embodiments where the second portion comprises glass, a metallizing ring may assist in bonding the first and second portions of the MEMS device. In some embodiments, the MEMS device (e.g., device 600, 700) manufactured by method 500 includes a bolometer and the cavity (e.g., cavity 608, 708) encloses a light sensor. In some embodiments, method 500 may further include coating the grooves with an adhesion layer prior to bonding the two portions. For example, FIGS. 6A and 6B depict adhesion layers 612 and 662, respectively. An adhesion layer can provide a surface for the preform solder or deposited solder to wet during bonding. In some embodiments, the adhesion layer can be applied in the bond region. In some embodiments, the adhesion layer can be applied in the bond region and in a portion of the cavity. For example, FIGS. 6A and 6B depict the adhesion layer applied in regions 614 and 664 of the cavities 608 and 658, respectively. An adhesion layer in the cavity may advantageously block incoming radiation from that portion of the cavity. In some embodiments, a reference bolometer is positioned below the adhesion layer, thereby eliminating other process steps that place an occlusion over a reference bolometer. This advantageous use of an adhesion layer in the cavity can be used with or without the grooves (or any other feature) disclosed herein. Although displayed in FIGS. 6A and 6B as adjacent the edge of active area, a reference sensor (and, consequently, the placement of the adhesion layer in the cavity) may not be adjacent the cavity. Exemplary methods of adding an adhesion layer including a lift off process or a mask.

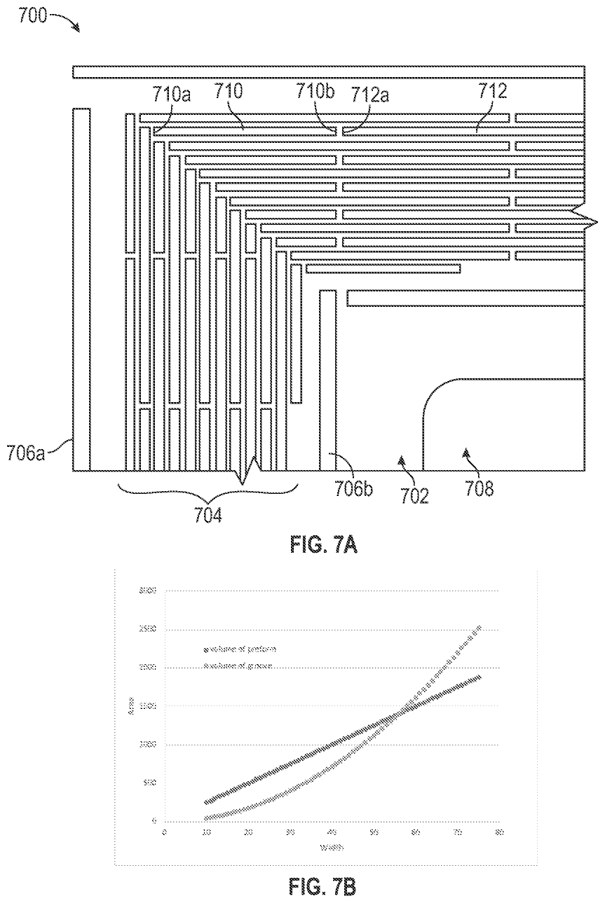

Turning to FIG. 8, a method 800 of manufacturing a plurality of MEMS devices is depicted, in accordance with an embodiment. Method 800 includes: a step 802 of providing a plurality of first electromechanical components; a step 804 in which a carrier is provided, the carrier including a plurality of positions, each associated with a respective one of the plurality of first electromechanical components; a step 806 of identifying a defective component in the plurality of first electromechanical components; a step 808 of providing a plurality of second electromechanical components; a step 810 of positioning the plurality of second electromechanical components at respective positions on the carrier but not a position associated with the defective electromechanical component; a step 812 in which respective pairs of first and second electromechanical components are bonded; and (optional) a step 814 of singulating the respective pairs of first and second electromechanical components to produce the plurality of MEMS devices.

In some embodiments, step 802 includes providing the plurality of components in a layer. In such embodiments, step 810 or step 812 includes positioning the layer on the carrier. In such embodiments, step 814 (singulating the respective pairs of first and second electromechanical components to produce the plurality of MEMS devices) can be used. In some embodiments, the layer is wafer size. Other layer sizes (e.g., panel scale) could be used without deviating from the scope of this disclosure. In some embodiments, the layer is round. Other layer shapes (e.g., square layers) could be used without deviating from the scope of this disclosure. In some embodiments, one or both of the first and second electromechanical components are round. Other component shapes (e.g., square component) could be used without deviating from the scope of this disclosure.

In some embodiments, step 804 includes providing a carrier with a plurality of cavities, each at a respective position of the carrier. In such embodiments, step 810 includes positioning the non-defective second electromechanical components in a respective cavity.

In some embodiments, step 806 includes electrically testing the plurality of electromechanical components. In some further embodiments, step 806 includes at least one of identifying a short circuit, identifying an open circuit, probing voltage ranges, and/or probing resistance value.

In some embodiments, step 806 mechanically testing the plurality of electromechanical components. Mechanical testing could include, for example, identifying a broken hinge, optical profilometry, and resonance frequency measurements. Mechanical testing can be performed using visual inspection tools.

In some embodiments, identifying a defective component (step 806) includes producing a bad device map. In some embodiments, the bad device map includes positions of known good components. In some embodiments, step 806 includes identifying more than one defective component.

In some embodiment, step 810 includes utilizing a pick-and-place machine to position the second electromechanical components. In some embodiments, an additional step removing the carrier is added to method 800.

In some embodiments, the MEMS devices is a bolometer and the first electromechanical components are bolometer covers.

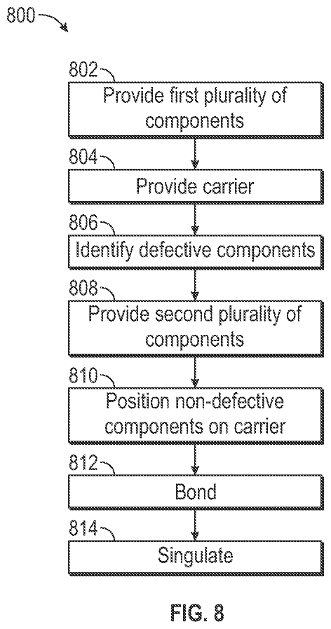

In some embodiments, the first electromechanical components include glass and the second electromechanical components include silicon. FIG. 9 depicts method 900 of manufacturing a plurality of MEMS devices, in accordance with an embodiment. In method 900, the first electrochemical component include glass (see 908) and the second electromechanical components include silicon (see 902). In method 900, the silicon is processed (step 902, listing exemplary processing steps of cavity etching, metallization, AR coating, and dicing) before individual silicon components are formed. Separately, method 900 includes providing (step 906) a square glass (an exemplary size of 150 mm is depicted). The glass can be provided to method 900 with some or all electromechanical components already added, or some or all of the electromechanical components are added to the glass wafer during method 900. Step 906 can further include additional (not illustrated) process steps, for example identifying defective components among the electromechanical components on the square glass. As step 910, a plurality of silicon electromechanical components are populated on the glass at positions corresponding to non-defective components of the glass. Step 912 includes bonding the silicon and glass components and step 914 includes singulating individual devices. In some embodiments the steps of method 900 correspond to or include the steps of method 800, and vice-versa.

In some embodiments, an electromechanical component includes an electrical component only, a mechanical component only, or both. In some embodiments, an electromechanical component includes a cover.

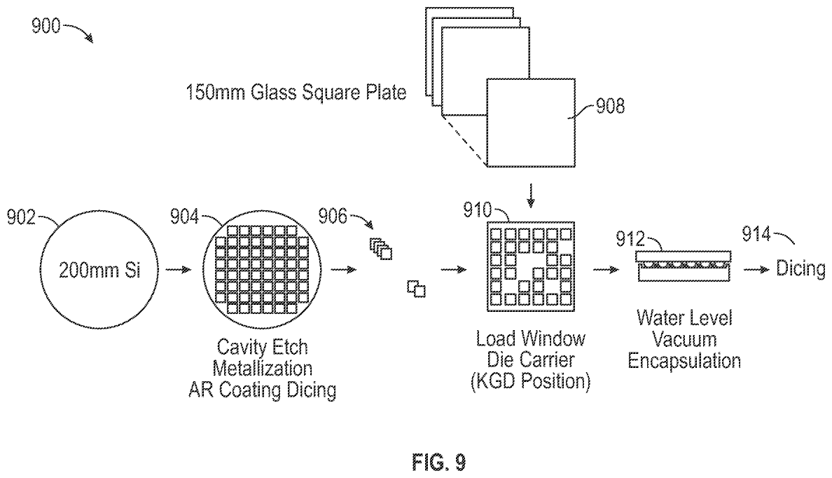

FIG. 10 illustrates a method 1000 of manufacturing an electromechanical system, in accordance with an embodiment. As non-limiting examples, the electrochemical system could be associated with the devices or systems described herein. To manufacture an electromechanical system, all or some of the process steps in method 1000 could be used and used in a different order. As a non-limiting example, Step 1014 could be performed before Step 1012. In some embodiments, steps of other methods disclosed herein can be performed with method 1000.

Method 1000 includes Step 1002, providing a substrate. In some embodiments, the substrate is made of glass. In some embodiments, the substrate is low temperature polycrystalline silicon. In some embodiments, the substrate is a borosilicate that contains additional elements to fine tune properties. An example of a borosilicate is by CORNING EAGLE, which produces an alkaline earth boro aluminosilicate (a silicate loaded with boron, aluminum, and various alkaline earth elements). Other variations are available from ASAHI GLASS or SCHOTT.

In some embodiments, a flat panel glass process is used to manufacture the electromechanical system. In some embodiments, a liquid crystal display (LCD) process is used to manufacture the electromechanical system. In some embodiments, an OLED display process or an x-ray panel process is used. Employing a flat panel glass process may allow for increased substrate sizes, thereby allowing for a higher number of electrochemical systems per substrate, which reduces processing costs. “Panel level” sizes can include 300 mm×400 mm, 360 mm×465 mm, 400 mm×500 mm, 550 mm×650 mm, 620 mm×750 mm, 680 mm×880 mm, 730 mm×920 mm, 1100 mm×1300 mm, 1300 mm×1500 mm, 1500 mm×1850 mm, 1950 mm×2250 mm, 2200 mm×2500 mm, and 2840 mm×3370 mm. Further, thin film transistors (TFTs) in panel level manufacturing can also reduce cost and so, for example, LCD-TFT processes can be beneficial.

Method 1000 includes Step 1004, adding MEMS to the substrate. Although MEMS is used to describe the addition of structures, it should be appreciated that other structures could be added without deviating from the scope of this disclosure. In embodiments using panel level processing, the MEMS structures may be added using an LCD-TFT process.

Step 1004 may be followed by optional Step 1016, sub-plating. Step 1016 may be used when the substrate is larger than the processing equipment used in subsequent steps. For example, if using a panel level process (such as LCD), some embodiments will include (at Step 1004) cutting the panel into wafer sizes to perform further processing (using, for example, CMOS manufacturing equipment). In other embodiments, the same size substrate is used throughout method 1000 (i.e., Step 1016 is not used).

Method 1000 includes Step 1006, releasing the MEMS from the substrate.

Method 1000 includes Step 1008, post-release processing. Such post-release processing may prepare the MEMS structure for further process steps, such as planarization. In wafer-level processing, planarization can include chemical mechanical planarization. In some embodiments, the further process steps include etch back, where a photoresist is spun onto the topography to generate a more planar surface, which is then etched. Higher control of the etch time can yield a smoother surface profile. In some embodiments, the further process steps include “spin on glass,” where glass-loaded organic binder is spun onto the topography and the result is baked to drive off organic solvents, leaving behind a surface that is smoother.

Method 1000 includes Step 1010, vacuum encapsulation of the MEMS structure, where necessary. Vacuum encapsulation may be beneficial to prolong device life.

Method 1000 includes Step 1012, singulation. Some embodiments may include calibration and chip programming, which may take into account the properties of the sensors. Methods described herein may be advantageous in glass substrate manufacturing processes because uniformity in glass lithography capabilities is limited. As a further advantage, glass has a lower thermal conductivity and so a glass substrate can be a better thermal insulator; by manufacturing thin structures separating a bolometer pixel from a glass substrate, embodiments herein may better serve to thermally isolate the glass bolometer pixel from the packaging environment.

Method 1000 includes Step 1014, attachment of a readout integrated circuit (ROIC) and flex/PCB attachment. Processes and devices described herein may have the further advantage that the area required for signal processing can be much smaller than the sensing area which is dictated by the sensing physics. Typically, sensors are integrated on top of CMOS circuitry, and area driven costs lead to a technology node that is not optimal for the signal processing task. Processes described herein can use a more suitable CMOS and drive down the area required for signal processing, freeing the sensor from any area constraints by leveraging the low cost of FPD (flat panel display) manufacturing. In some embodiments, the ROIC is specifically designed to meet requirements for sensing a specific electromagnetic wavelength (such as X-Rays, THz, LWIR).

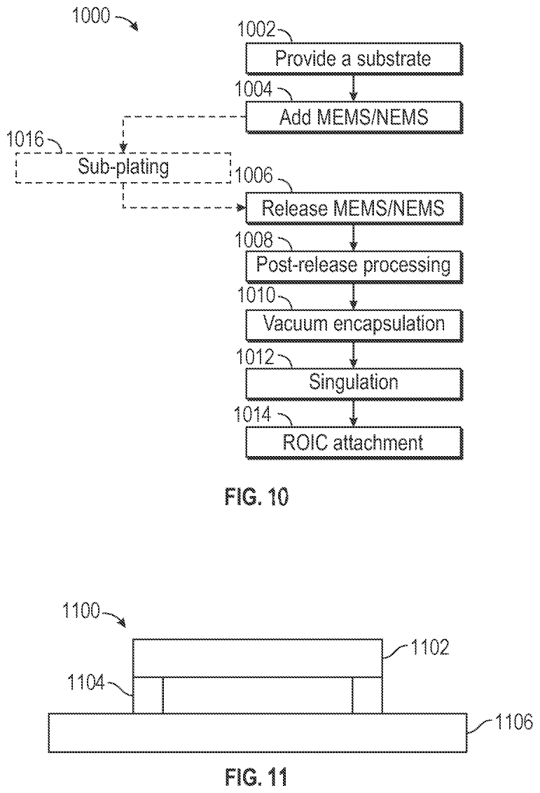

FIG. 11 illustrates an exemplary sensor. In some embodiments, sensor 1100 is manufactured using a method disclosed herein. Sensor 1100 includes glass substrate 1106, structure 1104 less than 250 nm wide coupled to glass substrate 1106, and a sensor pixel 1102 coupled to the structure 1104. In some embodiments of sensor 1100, structure 1104 is a hinge that thermally separates the active area from the glass. In some embodiments, sensor 1100 receives an input current or charge and outputs an output current or charge based on the received radiation (e.g., the resistance between two terminals of the sensor changes in response to exposure to LWIR radiation).

In some embodiments, a sensor includes a glass substrate, a structure manufactured from any of the methods described herein and coupled to the glass substrate, and a sensor pixel coupled to the structure. By way of examples, sensors can include resistive sensors and capacitive sensors.

In some embodiments, the MEMS devices manufactured by processes herein are bolometers, each including a glass substrate and a bolometer pixel coupled to the structure. In some embodiments, a bolometer includes a MEMS or NEMS device manufactured by an LCD-TFT manufacturing process.

Bolometers can be used in a variety of applications. For example, long wave infra-red (LWIR, wavelength of approximately 8-14 μm) bolometers can be used in the automotive and commercial security industries. For example, LWIR bolometers with QVGA, VGA, and other resolution. Terahertz (THz, wavelength of approximately 0.1 to 1.0 mm) bolometers can be used in security (e.g., airport passenger security screening) and medical (medical imaging). For example, THz bolometers can have the QVGA resolution (320×240) or other resolutions. Some electrochemical systems can include X-Ray sensors or camera systems. Similarly, LWIR and THz sensors are used in camera systems. Some electromechanical systems are applied in medical imaging, such as endoscopes and exoscopes.

Other electromechanical systems include scanners for light detection and ranging (LIDAR) systems. For example, optical scanners where spatial properties of a laser beam could be shaped (for, e.g., beam pointing). Electromechanical systems include inertial sensors (e.g., where the input stimulus is linear or angular motion). Some systems may be used in bio sensing and bio therapeutic platforms (e.g., where biochemical agents are detected).

As used herein, the term “MEMS” can be understood to include electromechanical systems having feature sizes of approximately 1 mm and below. For example, the term “MEMS” can be understood to include nano electromechanical systems (“NEMS”).

In a first embodiment, a method of manufacturing a plurality of MEMS devices, each device comprising a first material and a second material with different coefficients of thermal expansion (CTE), the method comprises: providing a carrier with substantially equal CTE as the first material, the carrier comprising a plurality of cavities; positioning a plurality of components in respective cavities of the carrier, the components comprising the second material; positioning a layer of the first material on the second material components; bonding the first material layer and the second material components; removing the carrier; and singulating the first material layer to produce the plurality of MEMS devices.

In second embodiment, the method of embodiment 1, wherein providing the carrier comprises providing a carrier layer of the first material.

In a third embodiment, the method of embodiment 1, wherein providing the carrier comprises providing at least one of a ceramic material or a metal.

In a fourth embodiment, the method of any of embodiments 1-3, wherein providing the carrier comprises: providing a first carrier layer; providing a second carrier layer; bonding the first and second carrier layers; removing material from one or both of the first and second carrier layers to create the plurality of cavities.

In a fifth embodiment, the method of any of embodiments 1-4, further comprising applying a vacuum, and wherein bonding the first material layer and second material components is performed while applying the vacuum.

In a sixth embodiment, the method of embodiment 5, wherein providing the carrier comprises providing a carrier with a vacuum channel in each cavity.

In a seventh embodiment, the method of any of embodiments 1-6, wherein providing the carrier comprises providing a round wafer.

In an eighth embodiment, the method of any of embodiments 1-6, wherein providing the carrier comprises providing a square wafer.

In a ninth embodiment, the method of any of embodiments 1-8, wherein providing the carrier comprises providing a 6-inch wafer.

In a tenth embodiment, the method of any of embodiments 1-8, wherein providing the carrier comprises providing an 8-inch wafer.

In an eleventh embodiment, the method of any of embodiments 1-6, wherein providing the carrier comprises providing a panel.

In a twelfth embodiment, the method of any of embodiments 1-11, wherein positioning the plurality of components comprises applying a vacuum to the components to secure the components to the carrier.

In a thirteenth embodiment, the method of embodiment 12, wherein providing the carrier comprises providing a carrier with a vacuum channel in each cavity, and wherein applying a vacuum comprises applying a vacuum to the components through the channel.

In a fourteenth embodiment, the method of any of embodiments 1-13, wherein each of the plurality of MEMS devices comprises a cover of the second material.

In a fifteenth embodiment, the method of any of embodiments 1-14, wherein each component comprises side walls with a metalized surface.

In a sixteenth embodiment, the method of embodiment 15, wherein each component's sidewalls define a cavity in the respective component.

In a seventeenth embodiment, the method of embodiment 16, further comprising creating the cavity in the respective component before positioning the components in the carrier.

In an eighteenth embodiment, the method of embodiment 16, further comprising creating the cavity in the respective component after positioning the components in the carrier.

In a nineteenth embodiment, the method of any of embodiments 15-18, further comprising creating the metalized surface before positioning the components in the carrier.

In a twentieth embodiment, the method of any of embodiments 15-18, further comprising creating the metalized surface after positioning the components in the carrier.

In a twenty first embodiment, the method of any of embodiments 15-20, wherein bonding the first material layer and the second material components comprises depositing bonding components on the metalized surfaces.

In a twenty second embodiment, the method of embodiment 21, wherein the bonding components comprise solder preforms, deposited solder, or both.

In a twenty third embodiment, the method of any of embodiments 1-22, wherein bonding the first material layer and the second material components comprises growing bonding components by deposition.

In a twenty fourth embodiment, the method of any of embodiments 1-23, wherein bonding the first material and second material comprises applying a temperature less than 350 C.

In a twenty fifth embodiment, the method of any of embodiments 1-24, wherein bonding the first material and second material comprises applying a temperature of approximately 300 C.

In a twenty sixth embodiment, the method of any of embodiments 1-25, further comprising rotating the first material layer, second material components, and carrier, after positioning the first material layer on the second material components and before bonding the first material layer and second material components.

In a twenty seventh embodiment, the method of any of embodiments 1-26, wherein singulating comprises dicing the first material layer using a dicing saw.

In a twenty eighth embodiment, the method of any of embodiments 1-26, wherein singulating comprises dicing the first material layer using a scribe and break process.

In a twenty ninth embodiment, the method of any of embodiments 1-28, wherein the first material and second material are selected from glass and silicon.

In a thirtieth embodiment, a MEMS device comprises: a first portion; and a second portion bonded to the first portion at a bond region, the bond region comprising a plurality of grooves.

In a thirty first embodiment, the MEMS device of embodiment 30, wherein the grooves comprise a V-shape.

In a thirty second embodiment, the MEMS device of any of embodiments 30-31, wherein the grooves are formed in a surface of the first portion and each groove comprises two side walls at about 54 degrees to the surface.

In a thirty third embodiment, the MEMS device of embodiment 30, wherein the grooves do not form an acute angle with the surface of the second portion.

In a thirty fourth embodiment, the MEMS device of any of embodiments 30-33, wherein the first portion comprises the grooves and a cavity deeper than the grooves.

In a thirty fifth embodiment, the MEMS device of embodiment 34, wherein the MEMS device comprises a bolometer and the cavity encloses a light sensor.

In a thirty sixth embodiment, the MEMS device of any of embodiments 30-35, wherein the plurality of grooves comprises multiple sectioned grooves arranged end-to-end.

In a thirty seventh embodiment, the MEMS device of any of embodiments 30-36, further comprising solder in the grooves and between the first and second portions.

In a thirty eighth embodiment, the MEMS device of embodiment 37, wherein the solder preform has a first volume, wherein the plurality of grooves define a second volume in the first portion, and wherein the second volume is greater than or equal to the first volume.

In a thirty ninth embodiment, the MEMS device of any of embodiments 30-38, further comprising an adhesive layer in the grooves and between the first and second portions.

In a fortieth embodiment, the MEMS device of any of embodiments 30-39, wherein the grooves are formed in a surface of the first portion and wherein the device further comprises a metalizing ring attached to the second portion.

In a forty first embodiment, a method of manufacturing a MEMS device, the device comprising a bond region, the method comprises: providing a first portion of the device; adding a plurality of grooves to the first portion at the bond region; positioning solder (e.g., solder preform, deposited solder) over the grooves; aligning a second portion of the device with the first portion; heating the solder; moving the first portion toward the second portion; and cooling the solder so that the first portion bonds to the second portion at the bond region.

In a forty second embodiment, the method of embodiment 41, wherein the grooves comprise side walls at about 54 degrees to a surface of the first portion.

In a forty third embodiment, the method of any of embodiments 41-42, wherein the solder has a first volume and the plurality of grooves define a second volume in the first portion, and wherein the second volume is greater than or equal to the first volume.

In a forty fourth embodiment, the method of any of embodiments 41-43, wherein the plurality of grooves comprises multiple sectioned grooves arranged end-to-end.

In a forty fifth embodiment, the method of any of embodiments 41-44, further comprising adding a metalizing ring to the second portion of the device.

In a forty sixth embodiment, the method of any of embodiments 41-45, further comprising adding a cavity to the first portion of the device, wherein the cavity is deeper than the grooves.

In a forty seventh embodiment, the method of embodiment 46, wherein the cavity and grooves are added to the first portion in a same etch processing step.

In a forty eighth embodiment, the method of embodiment 46, wherein the cavity and grooves are added to the first portion in different processing steps.

In a forty ninth embodiment, the method of any of embodiments 46-48, wherein the MEMS device comprises bolometers and the cavity encloses a light sensor.

In a fiftieth embodiment, the method of any of embodiments 41-49, further comprising at least one step in any of methods 1-29.

In a fifty first embodiment, a method of manufacturing a plurality of MEMS devices, the method comprising: providing a layer comprising a plurality of first electromechanical components; providing a carrier comprising a plurality of positions, each position associated with a respective one of the plurality of first electromechanical components; identifying a defective component in the plurality of first electromechanical components; positioning a plurality of second electromechanical components at respective positions on the carrier but not a position associated with the defective electromechanical component; positioning the layer on the carrier; bonding respective pairs of first and second electromechanical components; removing the carrier; and singulating the layer to produce the plurality of MEMS devices.

In a fifty second embodiment, the method of embodiment 51, wherein identifying the defective component comprises electrically testing the plurality of first electromechanical components.

In a fifty third embodiment, the method of embodiment 52, wherein identifying the defective component comprises identifying at least one of a short circuit or an open circuit.

In a fifty fourth embodiment, the method of any of embodiments 51-53, wherein identifying the defective component comprises mechanically testing the plurality of first electromechanical components.

In a fifty fifth embodiment, the method of any of embodiments 51-54, wherein identifying the defective component comprises producing a bad device map.

56. In a fifty sixth embodiment, the method of any of embodiments 51-55, wherein identifying the defective component comprises identifying more than one defective component and wherein positioning the plurality of second electromechanical components comprises positioning the plurality of second electromechanical components at respective positions on the carrier but not positions associated with the more than one defective electromechanical component.

In a fifty seventh embodiment, the method of any of embodiments 51-56, wherein the layer is wafer size.

In a fifty eighth embodiment, the method of any of embodiments 51-57, wherein the components are round.

In a fifty ninth embodiment, the method of any of embodiments 51-58, wherein the components comprise a bolometer cover.

In a sixtieth embodiment, the method of any of embodiments 51-59, wherein the components comprise silicon.

In a sixty first embodiment, the method of any embodiments 51-60 wherein the carrier comprises a plurality of cavities, each at a respective position of the carrier.

In a sixty second embodiment, the method of any of embodiments 51-61, further comprising at least one step in any of methods 1-29 and 41-49.

In a sixty third embodiment, a method of manufacturing a MEMS device, the method comprises: providing a transparent cover with a bond region and a cavity; and applying an adhesion layer in the bond region and in the cavity, wherein the adhesion layer is positioned in the cavity to block radiation reaching a reference sensor.

In a sixty fourth embodiment, the method of embodiment 63, further comprising at least one step in any of methods 1-29, 41-49, and 51-61.

In a sixty fifth embodiment, a MEMS device comprises: a substrate with a reference sensor and an active sensor; and a transparent cover comprising a bond region and a cavity, wherein the substrate and the transparent cover are bonded at the bond region using adhesive, and wherein the transparent cover comprises adhesive in the cavity positioned to block radiation reaching the reference sensor.

In a sixty sixth embodiment, the MEMS device of embodiment 65, wherein the cover further comprises a plurality of grooves in the bond region.

In a sixty seventh embodiment, the MEMS device of embodiment 66, wherein the grooves comprise a V shape.

In a sixty eighth embodiment, the MEMS device of any of embodiments 66-67, wherein the grooves are formed in a surface of the transparent cover and each groove comprises two side walls at about 54 degrees to the surface.

In a sixty ninth embodiment, the MEMS device of embodiment 66, wherein the grooves do not form an acute angle with the surface of the transparent cover.

In a seventieth embodiment, the MEMS device of any of embodiments 66-69, wherein the cavity is deeper than the grooves.

In a seventy first embodiment, the MEMS device of any of embodiments 66-70, wherein the plurality of grooves comprises multiple sectioned grooves arranged end-to-end.

In a seventy second embodiment, the MEMS device of any of embodiments 66-71, further comprising solder in the grooves and between the substrate and transparent cover.

In a seventy third embodiment, the MEMS device of embodiment 72, wherein the solder preform has a first volume, wherein the plurality of grooves define a second volume in the transparent cover, and wherein the second volume is greater than or equal to the first volume.

In a seventy fourth embodiment, the MEMS device of any of embodiments 66-73, wherein the grooves are formed in a surface of the transparent cover and wherein the device further comprises a metalizing ring attached to the substrate.

In a seventy fifth embodiment, the MEMS device of any of embodiments 65-74, wherein the MEMS device comprises a bolometer and the cavity encloses a light sensor.

Although the disclosed embodiments have been fully described with reference to the accompanying drawings, it is to be noted that various changes and modifications will become apparent to those skilled in the art. Such changes and modifications are to be understood as being included within the scope of the disclosed embodiments as defined by the appended claims. For example, although this disclosure is primarily described with respect to glass MEMS plates/panels, one of skill in the art will recognize that other MEMS plates/panels could also be used without deviating from the scope of the disclosure. Such others MEMS plates may include, but are not limited to, organic materials (plastics, polymers) and metals (e.g., stainless steel). As used herein, the terms “plate” and “panel” are synonymous.

The terminology used in the description of the various described embodiments herein is for the purpose of describing particular embodiments only and is not intended to be limiting. As used in the description of the various described embodiments and the appended claims, the singular forms “a”, “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

1. A MEMS device comprising:
a first portion; and
a second portion bonded to the first portion at a bond region, the bond region comprising a plurality of grooves.

2. The MEMS device of claim 1, wherein the grooves comprise a V-shape.

3. The MEMS device of claim 1, wherein the grooves are formed in a surface of the first portion and each groove comprises two side walls at about 54 degrees to the surface.

4. The MEMS device of claim 1, wherein the grooves do not form an acute angle with the surface of the second portion.

5. The MEMS device of claim 1, wherein the first portion comprises the grooves and a cavity deeper than the grooves.

6. The MEMS device of claim 5, wherein the MEMS device comprises a bolometer and the cavity encloses a light sensor.

7. The MEMS device of claim 1, wherein the plurality of grooves comprises multiple sectioned grooves arranged end-to-end.

8. The MEMS device of claim 1, further comprising solder in the grooves and between the first and second portions.

9. The MEMS device of claim 8, wherein
the solder preform has a first volume, wherein
the plurality of grooves define a second volume in the first portion, and wherein
the second volume is greater than or equal to the first volume.

10. The MEMS device of claim 1, further comprising an adhesive layer in the grooves and between the first and second portions.

11. The MEMS device of claim 1, wherein the grooves are formed in a surface of the first portion and wherein the device further comprises a metalizing ring attached to the second portion.

12. A method of manufacturing a MEMS device, the device comprising a bond region, the method comprising:
providing a first portion of the device;
adding a plurality of grooves to the first portion at the bond region;
positioning a solder preform over the grooves;
aligning a second portion of the device with the first portion;
heating the solder preform;
moving the first portion toward the second portion; and
cooling the solder preform so that the first portion bonds to the second portion at the bond region.

13. The method of claim 12, wherein the grooves comprise side walls at about 54 degrees to a surface of the first portion.

14. The method of claim 12, wherein the solder preform has a first volume and the plurality of grooves define a second volume in the first portion, and wherein the second volume is greater than or equal to the first volume.

15. The method of claim 12, wherein the plurality of grooves comprises multiple sectioned grooves arranged end-to-end.

16. The method of claim 12, further comprising adding a metalizing ring to the second portion of the device.

17. The method of claim 12, further comprising adding a cavity to the first portion of the device, wherein the cavity is deeper than the grooves.

18. The method of claim 17, wherein the cavity and grooves are added to the first portion in a same etch processing step.

19. The method of claim 17, wherein the cavity and grooves are added to the first portion in different processing steps.

20. The method of claim 17, wherein the MEMS device comprises bolometers and the cavity encloses a light sensor.
